(19) United States
(12) Patent Application Publication
(10) Pub. No.: US 2026/0076041 A1
(43) Pub. Date: Mar. 12, 2026

(54) Display Apparatus

(71) Applicant: LG Display Co., Ltd., Seoul (KR)

(72) Inventors: Sunggon Hong, Paju-si (KR); Donghyun Byun, Paju-si (KR); Taeryong Kim, Paju-si (KR); Jongchan Park, Paju-si (KR)

(21) Appl. No.: 19/232,443

(22) Filed: Jun. 9, 2025

(30) Foreign Application Priority Data
Sep. 9, 2024 (KR) 10-2024-0122006

(51) Int. Cl. H10K 59/122; H10K 59/121; H10K 59/80; H10K 102/00

(52) U.S. Cl. CPC H10K 59/122; H10K 59/1213; H10K 59/873; H10K 2102/311

(57) ABSTRACT

A display apparatus comprising: a substrate including a display area having sub-pixels; first and second thin-film transistors on the substrate; organic insulating layers on the first and second thin-film transistors, the organic insulating layers having a concave portion; a first electrode on a peripheral portion located around and on the concave portion; a first bank on the first electrode; a second bank on the first bank and including a first portion on the first electrode in a region corresponding to the concave portion and a second portion on the first electrode and the organic insulating layer in a region corresponding to the peripheral portion; an organic layer overlapping with the concave portion and on the first electrode; a second electrode on the organic layer and the second bank encapsulation layers on the second electrode; a touch layer on the encapsulation layers; and a color filter layer on the touch layer.

### CROSS REFERENCE TO RELATED APPLICATION

The present application claims priority to Republic of Korea Patent Application No. 10-2024-0122006, filed on Sep. 9, 2024, which is hereby incorporated by reference in its entirety.

### BACKGROUND

### Field of Technology

This specification relates to a display apparatus.

### Description of the Related Art

With the advancement of the information society, there is an increasing demand for display apparatuses that can show images, and various types of display apparatuses such as liquid crystal display (LCD) apparatuses and organic light emitting diode (OLED) display apparatuses are being utilized. In particular, OLED display apparatuses, which do not require a separate light source, have been growing demand due to their advantages in being lightweight and thin.

However, the organic light-emitting display panel includes an organic layer that emits light, and some of the light emitted from the organic layer becomes trapped inside the device instead of escaping to the outside, resulting in reduced light extraction efficiency and decreased light emission efficiency.

### SUMMARY

It is an object of the embodiments of this specification to provide a display apparatus with improved light extraction efficiency.

It is another object of the embodiments of this specification to provide a display apparatus capable of improving the spreadability of a third encapsulation layer (or organic encapsulation layer) by applying a protruding structure or an angular structure to a second bank.

It is another object of the embodiments of this specification to provide a display apparatus having a structure capable of preventing color mixing between adjacent sub-pixels.

It is still another object of the embodiments of this specification to provide a display apparatus capable of reducing leakage current between adjacent sub-pixels by forming trenches in an organic insulating layer and a second bank, increasing the resistance of a thinned light-emitting layer.

The objects of this specification are not limited to the aforesaid, and other objects not described herein will be clearly understood by those skilled in the art from the descriptions below.

In order to accomplish the above objects, a display apparatus according to an embodiment may include a substrate including a display area having a plurality of sub-pixels and a non-display area surrounding the display area, a first thin-film transistor and a second thin-film transistor disposed on the substrate and spaced apart from each other, a plurality of organic insulating layers disposed on the first thin-film transistor and the second thin-film transistor, the plurality of organic insulating layers having at least one concave portion, a first electrode disposed on a peripheral portion located around the concave portion and on the concave portion, a first bank disposed on the first electrode; a second bank disposed on the first bank, the second bank including a first portion disposed on the first electrode in a region corresponding to the concave portion and a second portion disposed on the first electrode and the organic insulating layer in a region corresponding to the peripheral portion, an organic layer overlapping with the concave portion and disposed on the first electrode, a second electrode disposed on the organic layer and the second bank, a plurality of encapsulation layers disposed on the second electrode, a touch layer disposed on the plurality of encapsulation layers, and a color filter layer disposed on the touch layer.

### BRIEF DESCRIPTION OF THE DRAWINGS

FIG. 1 is a plan view of a display apparatus according to an embodiment;

FIG. 2 is a cross-sectional view of the display panel of FIG. 1 in a bent state according to an embodiment;

FIG. 3 is a plan view illustrating the arrangement of sub-pixels in the display area of FIG. 1 according to an embodiment;

FIG. 4 is a cross-sectional view taken along line A-A′ of FIG. 3 according to an embodiment;

FIG. 5 is an enlarged cross-sectional view of region X in FIG. 4 according to an embodiment;

FIG. 6 is a cross-sectional view of the touch layer according to FIG. 4 according to an embodiment;

FIG. 7 is a cross-sectional view taken along line B-B′ of FIG. 1 according to an embodiment;

FIG. 8 is a cross-sectional view taken along line C-C′ of FIG. 1 according to an embodiment; and

FIG. 9 is a plan view illustrating the arrangement of sub-pixels in the display area of FIG. 1 according to an alternative embodiment.

### DETAILED DESCRIPTION

Advantages and features disclosed in this specification and methods of accomplishing the same may be understood more readily by reference to the detailed description of embodiments that will be made hereinafter with reference to the accompanying drawings. This specification is not limited to the embodiments described herein but may be embodied in various forms, and the embodiments are provided to ensure a complete disclosure of the invention and to fully convey the scope of the specification to those skilled in the art in the relevant technical field.

The shapes, sizes, ratios, angles, numbers, and the like illustrated in the drawings for describing the embodiments of the invention are exemplary, and thus the invention is not limited to these illustrations. Throughout the specification, the same reference numerals refer to the same components. In addition, detailed descriptions of well-known technologies may be omitted in the specification to avoid obscuring the subject matter of the specification. When terms such as “comprises,” “has,” “includes,” or “is made up of” are used in this specification, it should be understood that unless “only” is specifically used, additional elements or steps can be included. Unless otherwise explicitly stated, when a component is expressed in the singular form, it is intended to encompass the plural form as well.

In interpreting the components, it is construed to include a margin of error even in the absence of explicit description.

In the case of describing positional relationships, for example, when the positional relationship between two components is described using terms such as “on,′ “on top of,” “below,” or “beside,” one or more other components may be positioned between the two components unless “directly” or “immediately” is specified.

When a device or layer is referred to as being “on” another device or layer, it includes cases where one device or the layer is directly located on the other device or the layer or still another device or layer is interposed between the two devices or layers.

Although the terms “first”, “second”, and the like are used for describing various components, these components are not confined by these terms. These terms are merely used for distinguishing one component from the other components. Although the terms “first”, “second”, and the like are used for describing various components, these components are not confined by these terms.

Throughout the specification, the same reference numerals refer to the same components.

The area and thickness of each component shown in the drawings are illustrated for the convenience of description, and this specification is not necessarily limited to the area and thickness of the components as illustrated.

The various features of the embodiments of the disclosure can combined or assembled together, either partially or entirely, in a technically diverse manner, and each embodiment can be independently implemented or in conjunction with related embodiments.

Hereinafter, the embodiments of this specification will be described with reference to the accompanying drawings.

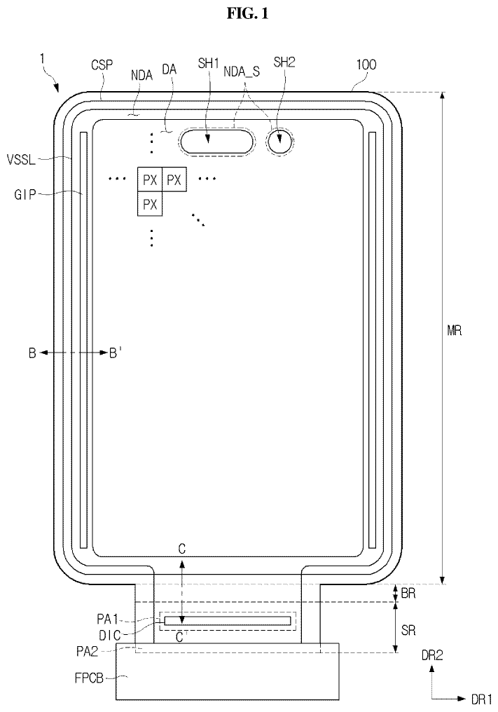

FIG. 1 is a plan view of a display apparatus according to an embodiment.

Referring to FIG. 1, a display apparatus 1 according to an embodiment may include a display panel 100. The display panel 100 may include a display area DA including a plurality of pixels PX and a non-display area NDA surrounding the display area DA. The display area DA may have a rectangular planar shape. However, the display area DA is not limited thereto and may have a square, circular, elliptical, or other polygonal planar shape. For example, the display area DA may have a rectangular shape with rounded corners, but is not limited thereto, and may also have a rectangular shape with angular corners.

In the embodiments herein, the first direction DR1 and the second direction DR2 are different directions that intersect each other, for example, directions that intersect perpendicularly in a plan view. In FIG. 1, the first direction DR1 generally corresponds to the extension direction of the short sides of the display panel 100, and the second direction DR2 may correspond to the extension direction of the long sides of the display panel 100. However, the directions mentioned in the embodiments should be understood as relative directions, and the embodiments are not limited to the directions mentioned.

The display area DA may include short sides extending along the first direction DR1 and long sides extending along the second direction DR2. The non-display area NDA may surround the display area DA. The non-display area NDA may be disposed on one side and the other side of the display area DA in the first direction DR1 and on one side and the other side of the display area DA in the second direction DR2.

The display panel 100 may further include a sensor non-display areas NDA_S and a sensor hole surrounded by the sensor non-display area NDA_S. The sensor holes SH1 and SH2 may be surrounded by the display area DA in a plan view. The sensor holes SH1 and SH2 may, for example, be two in number as shown in FIG. 1, but the embodiments of this specification are not limited thereto. For example, a single sensor hole may be provided. The two sensor holes SH1 and SH2 may be provided for the arrangement of an infrared sensor and a camera sensor, respectively; however, the embodiments of this specification are not limited to this configuration. The sensor non-display area NDA_S may be disposed between the sensor holes SH1 and SH2 and the display area DA. The sensor non-display area NDA_S may completely surround the sensor holes SH1 and SH2. No pixels PX may be arranged in the sensor non-display area NDA_S.

A gate driving unit GIP may be arranged in the non-display area NDA located on each of one side and another side of the display area DA in the first direction DR1. A low-potential voltage line VSSL may be disposed outside the gate driving unit GIP in the non-display area NDA. For example, as shown in FIG. 1, the low-potential voltage line VSSL may extend from a flexible printed circuit board FPCB, pass through a sub-region SR and a bending region BR, and be positioned outside the gate driving unit GIP in the non-display area NDA while surrounding the display area DA.

The non-display area NDA located on the opposite side of the display area DA in the second direction DR2 may extend further in the second direction DR2 from the central portion of that side of the display area DA. The width in the first direction DR1 of the non-display area NDA, which extends further in the second direction DR2 from the central portion of the opposite side of the display area DA in the second direction DR2, may be smaller than the width in the first direction DR1 of the non-display area NDA adjacent to the opposite side of the display area DA in the second direction DR2.

The display apparatus 1 may include a main region MR, a sub-region SR, and a bending region BR between the main region MR and the sub-region SR. The display area DA and the non-display area NDA surrounding the display area DA on all four sides may form the main region MR, while the portion extending further in the second direction DR2 from the central portion of the other side of the display area DA may constitute the bending region BR and the sub-region SR. The bending region BR may be positioned between the sub-region SR and the main region MR. The sub-region SR may include a first pad area PA1 and a second pad area PA2 located at the opposite end of the sub-region SR in the second direction DR2. The display apparatus 1 may further include a data driver DIC and a printed circuit board FPCB. The data driver DIC may be placed in the first pad area PA1, and the flexible printed circuit board FPCB may be attached to the second pad area PA2. The first pad area PA1 and the second pad area PA2 may each include a number of pads that connect the data driver DIC and the flexible printed circuit board FPCB. The data driver DIC may, for example, be provided in the form of a driving chip integrated circuit (IC), but is not limited thereto. In an embodiment, the data driver DIC is arranged in a chip-on-plastic method, directly mounted on the display panel 100, but is not limited thereto, and may also be arranged in a chip-on-glass or chip-on-film method.

The display panel 100 according to an embodiment may further include a crack detection pattern CSP surrounding the low-potential voltage line VSSL. The crack detection pattern CSP may be arranged to completely surround the display area DA, as shown in FIG. 1. For example, the crack detection pattern CSP may be placed on the outer side of the low-potential voltage line VSSL. However, the embodiments of this specification are not limited thereto, and the crack detection pattern CSP may not be partially disposed in the non-display area NDA on the opposite side of the display area DA in the second direction DR2.

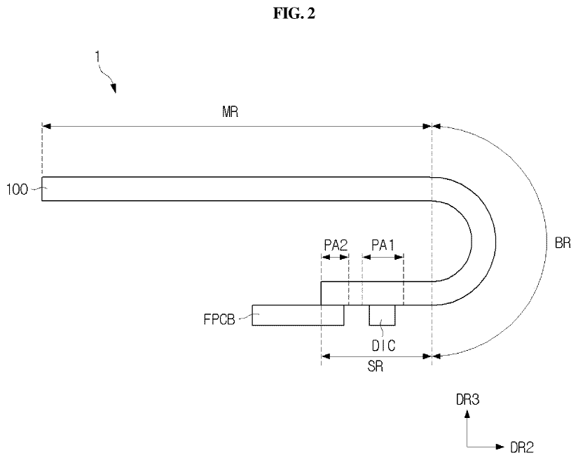

FIG. 2 is a cross-sectional view illustrating a bent state of the display panel in FIG. 1 according to an embodiment.

Referring to FIG. 2, the bending region BR of the display panel 100 of the display apparatus 1 according to an embodiment may be bent in the thickness direction (or the third direction DR3). Through this, the main region MR and the sub-region SR may overlap in the thickness direction. The display panel 100 may be bent such that the bottom surface of the main region MR and the top surface of the sub-region SR face each other. A flexible printed circuit board FPCB may be attached to the end of the sub-region SR.

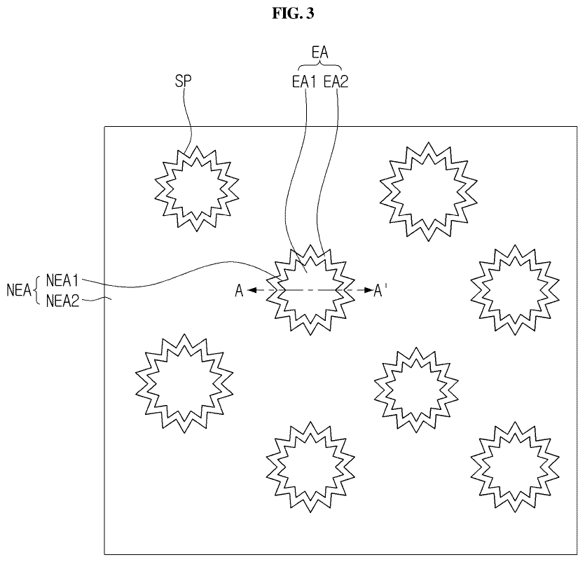

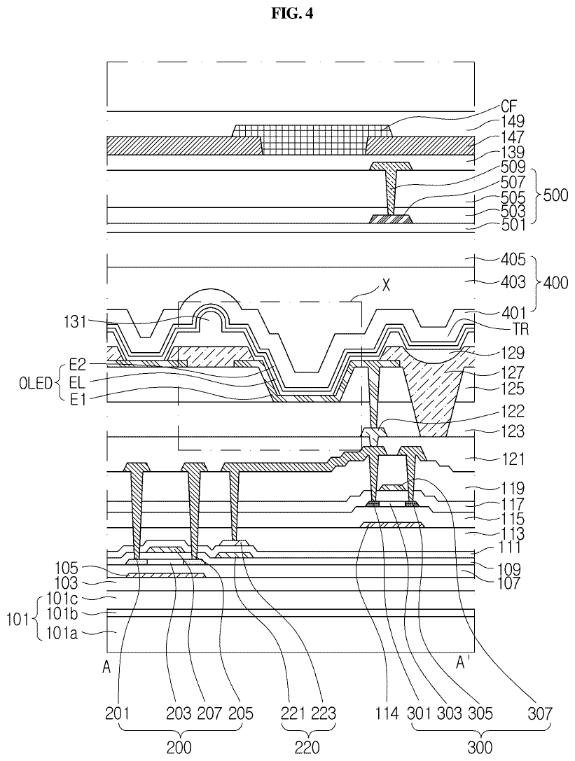

FIG. 3 is a plan view illustrating the arrangement of sub-pixels in the display area of FIG. 1 according to an embodiment. FIG. 4 is a cross-sectional view taken along line A-A′ of FIG. 3 according to an embodiment. FIG. 4 may be a diagram illustrating only some components and some regions disposed in one sub-pixel SP, or it may be a diagram illustrating only some components and some regions disposed in the pad area.

Referring to FIG. 3, a plan view illustrating a plurality of emissive areas EA and a plurality of non-emissive areas NEA included in the display area DA of the display panel 100 is shown.

As shown in FIG. 3, the area of the emissive areas EA of at least two sub-pixels SP may differ, but the present disclosure is not limited to such differences.

Each sub-pixel SP disposed in the display area DA may include a plurality of emissive areas EA1 and EA2. Specifically, one sub-pixel SP may include a first emissive area EA1 and a second emissive area EA2 surrounding the first emissive area EA1. A first non-emissive area NEA1 may be disposed between the first emissive area EA1 and the second emissive area EA2. That is, the first emissive area EA1 and the second emissive area EA2 may be separated by the first non-emissive area NEA1.

As shown in FIG. 3, the first emissive area EA1, the second emissive area EA2, and the first non-emissive area NEA1 may have a protruding shape with a plurality of protrusions in a plan view. However, this specification is not limited thereto, and the first emissive area EA1, the second emissive area EA2, and the first non-emissive area NEA1 may have a polygonal shape in a plan view, such as a triangle, quadrangle, or hexagon, or a combination of such shapes.

A pair of first and second emissive areas EA1 and EA2 may be spaced apart from another pair of first and second emissive areas EA1 and EA2, and a second non-emissive area NEA2 may be disposed between the pairs of first and second emissive areas EA1 and EA2.

The second non-emissive area NEA2 may correspond to a portion or the entirety of a circuit region where a circuit for driving the first and second emissive areas EA1 and EA2 is disposed.

Referring to FIG. 4, a pixel PX of the display panel 100 (FIG. 1) may include a plurality of sub-pixels. Each sub-pixel may be a red, green, blue, or white sub-pixel, but the embodiments of the specification are not limited thereto.

The display panel 100 may include a substrate 101, a first thin-film transistor 200, a second thin-film transistor 300, an organic light-emitting diode OLED, an encapsulation layer 400, a touch layer 500, a black matrix 147, a color filter CF, and a planarization layer 149.

The display panel 100 may include at least one panel insulating layer between the substrate 101 and the organic light-emitting diode OLED. At least one panel insulating layer may include at least one of the multi-buffer layer 103, the first insulating layer 107, the second insulating layer 109, the third insulating layer 111, the fourth insulating layer 113, the fifth insulating layer 115, the sixth insulating layer 117, the seventh insulating layer 119, the first organic insulating layer 121, the second organic insulating layer 123, and the third organic insulating layer 125 described above. At least one touch layer may be disposed on the organic light-emitting diode OLED. At least one touch insulating layer may include at least one of the touch buffer layer 501, the first touch insulating layer 503, and the second touch insulating layer 505.

The substrate 101 may include one or more plastic materials. For example, the substrate 101 may be a multi-substrate including a plurality of plastic materials, such as polyimide. For example, the substrate 101 may include a first substrate portion 101a and a second substrate portion 101b, each including a plastic material, and a third substrate portion 101c, which includes an inorganic insulating material between the first and second substrate portions 101a and 101b, but the embodiments of this specification are not limited thereto.

A multi-buffer layer 103 may be disposed on the substrate 101. The multi-buffer layer 103 may minimize or delay the diffusion of moisture or oxygen penetrating the substrate 101. The buffer layer 101 may be formed by alternately stacking silicon nitride (SiNₓ) and silicon oxide (SiOₓ) at least once, but the embodiments of this specification are not limited thereto.

A first light-shielding layer 105 may be disposed on the multi-buffer layer 103. The first light-shielding layer 105 may prevent light from passing through the first semiconductor layer 203 of the first thin-film transistor 200. For example, the first semiconductor layer 203 may be disposed to overlap with the first light-shielding layer 105. The first light-shielding layer 105 may be a single layer or multiple layers made of molybdenum (Mo), aluminum (Al), chromium (Cr), nickel (Ni), neodymium (Nd), copper (Cu), or any of their alloys, but the embodiments of this specification are not limited thereto.

A first insulating layer 107 may be disposed on the multi-buffer layer 103 and the first light-shielding layer 105. The first insulating layer 107 may prevent or at least reduce a likelihood of a short circuit between the configuration of the first thin-film transistor 200 and the first light-shielding layer 105. The first insulating layer 107 may be made of the same material as the multi-buffer layer 103, but the embodiments of this specification are not limited thereto. For example, the first insulating layer 107 may be made of an inorganic insulating material, such as silicon nitride (SiNₓ) or silicon oxide (SiOₓ), but the embodiments of this specification are not limited thereto.

A first thin-film transistor 200 may be disposed on the first insulating layer 107. The first thin-film transistor 200 may include a first source electrode 201, a first semiconductor layer 203, a first drain electrode 205, and a first gate electrode 207.

The first semiconductor layer 203 may be disposed on the first insulating layer 107. The first semiconductor layer 203 may include a silicon-based semiconductor material, such as amorphous silicon or polycrystalline silicon, but the embodiments of this specification are not limited thereto. The first semiconductor layer 203 may be formed of a metal oxide semiconductor, such as indium-gallium-zinc oxide. The first semiconductor layer 203 may include a channel region, a source region, and a drain region.

The polycrystalline semiconductor layer has higher mobility than the amorphous semiconductor layer and the oxide semiconductor layer, so it may have lower power consumption and improved reliability. Therefore, the first thin-film transistor 200 used as a switching transistor may be formed using a polycrystalline semiconductor layer.

A second insulating layer 109 may be disposed on the first semiconductor layer 203. The second insulating layer 109 may be made of the same material as the first insulating layer 107 and may prevent short circuits between the first semiconductor layer 203 and other components of the first thin-film transistor 200.

A first gate electrode 207 may be disposed on the second insulating layer 109. The first gate electrode 207 may be arranged to overlap with the channel region of the first semiconductor layer 203, positioned on the second insulating layer 109. The first gate electrode 207 may be composed of a single layer or multilayer structure that includes materials such as molybdenum (Mo), copper (Cu), titanium (Ti), aluminum (Al), chromium (Cr), gold (Au), nickel (Ni), neodymium (Nd), or their compounds, but the embodiments of this specification are not limited to these materials. The first gate electrode 207 may be arranged along with a gate line.

A third insulating layer 111 may be disposed on the first gate electrode 207. The third insulating layer 111 may be formed by alternately stacking silicon nitride and silicon oxide at least once, but the embodiments of this specification are not limited thereto.

A first source electrode 201 and a first drain electrode 205 may be disposed on the third insulating layer 111.

The first source electrode 201 and the first drain electrode 205 may be electrically connected to the first semiconductor layer 203 through contact holes. The first source electrode 201 and the first drain electrode 205 may be made of a metal material. For example, the first source electrode 201 and the first drain electrode 205 may be composed of a single layer or multiple layers made of any one of molybdenum (Mo), aluminum (Al), chromium (Cr), gold (Au), titanium (Ti), nickel (Ni), neodymium (Nd), copper (Cu), or their alloys, but the embodiments of this specification are not limited thereto.

The first source electrode 201 and the first drain electrode 205 may be arranged along with the data line. For example, the data line may be formed in the same layer and made of the same material as the first source electrode 201 and the first drain electrode 205, but the embodiments of this specification are not limited thereto.

The storage electrode 220 may be disposed apart from the first thin-film transistor 200. The storage electrode 220 may include a first storage electrode 221 and a second storage electrode 223.

The first storage electrode 221 may be disposed in the same layer and made of the same material as the first gate electrode 207, but the embodiments of this specification are not limited thereto.

The second storage electrode 223 may be disposed on the first storage electrode 221. The second storage electrode 223 may be disposed on the third insulating layer 111, and a capacitance may be formed by using the third insulating layer 111 as a dielectric between the first storage electrode 221 and the second storage electrode 223. The second storage electrode 223 may be made of the same material as the first storage electrode 221, but the embodiments of this specification are not limited thereto.

The second thin-film transistor 300 may be disposed spaced apart from the first thin-film transistor 200 and the storage electrode 220. The second thin-film transistor 300 may include a second source electrode 301, a second semiconductor layer 303, a second drain electrode 305, and a second gate electrode 307.

The second source electrode 301 may be formed of the same material as the first source electrode 201. The second drain electrode 305 may be formed of the same material as the first drain electrode 205.

The fourth insulating layer 113 may be disposed on the storage electrode 220. The second light-shielding layer 114 may be disposed on the fourth insulating layer 113.

The second light-shielding layer 114, similar to the first light-shielding layer 105, may prevent or at least reduce light from reaching the second semiconductor layer 303, thereby extending the lifespan of the second thin-film transistor 300. For example, the second semiconductor layer 303 may be disposed to overlap with the second light-shielding layer 114.

The fifth insulating layer 115 may be disposed on the second light-shielding layer 114. The fifth insulating layer 115 may be formed of the same material as the first insulating layer 107, the second insulating layer 109, the third insulating layer 111, and the fourth insulating layer 113, but the embodiments of this specification are not limited thereto.

The second semiconductor layer 303 may be disposed on the fifth insulating layer 115. The second semiconductor layer 303 may include a source region, a drain region, and a channel region between the source and drain regions.

The second semiconductor layer 303 may include a semiconductor material such as a metal oxide semiconductor like Indium-Gallium-Zinc Oxide (IGZO), or a silicon-based semiconductor material such as amorphous silicon or polycrystalline silicon, but the embodiments of this specification are not limited thereto.

The fifth insulating layer 117 may be disposed on the second semiconductor layer 303. The sixth insulating layer 117 may be made of the same material as the first insulating layer 107, second insulating layer 109, third insulating layer 111, fourth insulating layer 113, or fifth insulating layer 115, but the embodiments of this specification are not limited thereto.

The second gate electrode 307 may be disposed on the sixth insulating layer 117. The second gate electrode 307 may be made of the same material as the first gate electrode 207. For example, the second gate electrode 307 may be formed as a single layer or multiple layers made from materials such as molybdenum (Mo), copper (Cu), titanium (Ti), aluminum (Al), chromium (Cr), gold (Au), nickel (Ni), neodymium (Nd), or alloys of these materials, but the embodiments of this specification are not limited thereto

The seventh insulating layer 119 may be disposed on the second gate electrode 307. The seventh insulating layer 119 may be formed of the same material as the first insulating layer 107, the second insulating layer 109, the third insulating layer 111, the fourth insulating layer 113, the fifth insulating layer 115, or the sixth insulating layer 117; however, the embodiments of this specification are not limited thereto.

The first source electrode 201, first drain electrode 205, second source electrode 301, and second drain electrode 305 may be disposed on the seventh insulating layer 119.

The second source electrode 301 and second drain electrode 305 may be made of the same material as the first source electrode 201 and first drain electrode 205 and may be disposed in the same layer, but the embodiments of this specification are not limited thereto. For example, the second source electrode 301 and second drain electrode 305 may be formed as a single layer or multiple layers made from materials such as molybdenum (Mo), aluminum (Al), chromium (Cr), gold (Au), titanium (Ti), nickel (Ni), neodymium (Nd), and copper (Cu) or alloys of these materials, but the embodiments of this specification are not limited thereto. For example, the second source electrode 301 may be electrically connected to the second storage electrode 223. The second source electrode 301 may pass through the seventh insulating layer 119, the sixth insulating layer 117, the fifth insulating layer 115, and the fourth insulating layer 113 to be electrically connected to the second storage electrode 223.

The first thin-film transistor 200 may be a switching transistor, and the second thin-film transistor 300 may be a driving transistor; however, the embodiments of this specification are not limited thereto.

The first organic insulating layer 121 may be disposed on the second transistor 300. The first organic insulating layer 121 may planarize and protect the upper portions of the first transistor 200 and the second transistor 300. The first organic insulating layer 121 may be formed of an organic material. For example, the first organic insulating layer 121 may be formed of an organic material including acrylic resin, epoxy resin, phenolic resin, polyamide resin, or polyimide resin, but the embodiments of this specification are not limited thereto.

The second organic insulating layer 123 may be disposed on the first organic insulating layer 121. The second organic insulating layer 123 may be formed of the same material as the first organic insulating layer 121, but the embodiments of this specification are not limited thereto.

The third organic insulating layer 125 may be disposed on the second organic insulating layer 123. The third organic insulating layer 125 may be formed of the same material as the second organic insulating layer 123 or the first organic insulating layer 121, but the embodiments of this specification are not limited thereto.

The fourth organic insulating layer (not shown) may be further disposed on the third organic insulating layer 125, but the embodiments of this specification are not limited thereto.

A connection electrode 122 may be disposed between the first organic insulating layer 121 and the second organic insulating layer 123.

The connection electrode 122 may electrically connect the first thin-film transistor 200 to the organic light-emitting diode OLED. The connection electrode 122 may be a single layer or multilayer made of materials such as molybdenum (Mo), aluminum (Al), chromium (Cr), gold (Au), titanium (Ti), nickel (Ni), neodymium (Nd), and copper (Cu) or alloys of these materials, but the embodiments of this specification are not limited thereto.

The organic light-emitting diode OLED may be disposed on the third organic insulating layer 125 and the second organic insulating layer 123. The organic light-emitting diode OLED includes a first electrode E1, a light-emitting layer EL, and a second electrode E2. The first electrode E1 may be an anode electrode, and the second electrode E2 may be a cathode electrode, but this specification is not limited thereto.

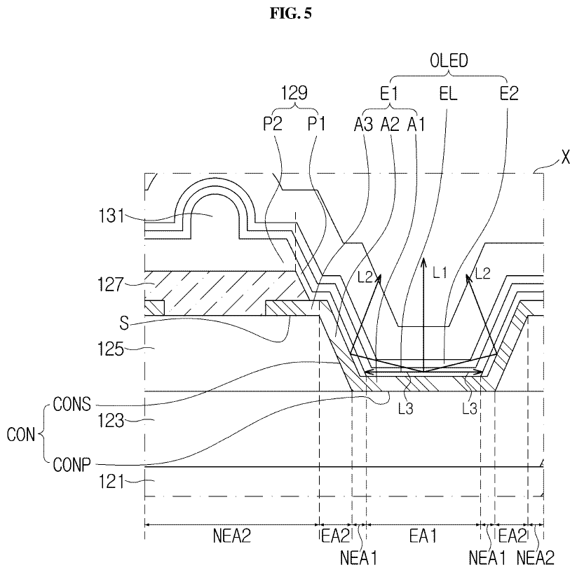

The third organic insulating layer 125 may have at least one concave portion in one sub-pixel area. The specific shape of the concave portion will be described with reference to FIG. 5, which is an enlarged view of region X in FIG. 4.

The first electrode E1 may be connected to the connection electrode 122 through a contact hole formed in the second organic insulating layer 123 and the third organic insulating layer 125. The first electrode E1 may also be electrically connected to the second thin-film transistor 300 through the connection electrode 122. The first electrode E1 may be a reflective electrode that reflects light, but the embodiments of this specification are not limited thereto. The first electrode E1 may include a metal material with high reflectivity, such as a stacked structure of aluminum (Al) and titanium (Ti) in the form of Ti/Al/Ti, a stacked structure of aluminum (Al) and (ITO) in the form of ITO/Al/ITO, or an APC alloy, and may be formed as a single layer or a multilayer, but the embodiments of this specification are not limited thereto.

The light-emitting layer EL may be disposed on the first electrode E1. The light-emitting layer EL may include one or more light-emitting structures (or light-emitting elements) stacked on the first electrode E1 in the order of a hole transport layer and an electron transport layer, or in the reverse order. For example, the hole delivery layer may include a hole transport layer, hole injecting layer, electron blocking layer, or P-type charge generating layer, but the embodiments of this specification are not limited thereto. For example, the electron delivery layer may include an electron transport layer, electron injecting layer, hole blocking layer, or N-type charge generating layer, but the embodiments of this specification are not limited thereto.

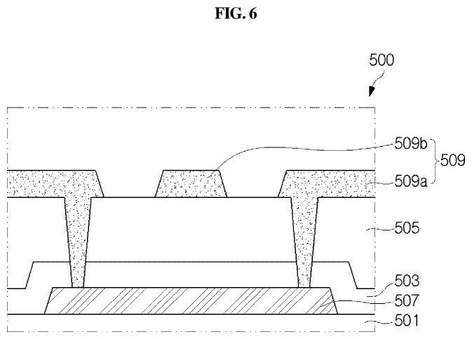

The light-emitting layer EL may be an organic light-emitting layer, an inorganic light-emitting layer, a quantum dot light-emitting layer, a micro light-emitting diode, or a micro-mini light-emitting diode, but the embodiments of this specification are not limited thereto. For example, the light-emitting layer EL of the display panel 100 according to an embodiment of this specification may include an organic light-emitting layer. The light-emitting layer EL may include a red light-emitting layer, a green light-emitting layer, and a blue light-emitting layer. The light-emitting layer EL may further include a white light-emitting layer, but the embodiments of this specification are not limited thereto. FIG. 6 is a cross-sectional view of the touch layer according to FIG. 4. The detailed structure of the light-emitting layer EL according to an embodiment will be described with reference to FIG. 6.

The second electrode E2 may be disposed on the light-emitting layer EL. The second electrode E2 may be a transparent electrode that transmits light, but the embodiments of this specification are not limited thereto. For example, the second electrode E2 may include a transparent conductive material, such as indium tin oxide (ITO) or indium zinc oxide (IZO), or a metal through which visible light is transmitted, but the embodiments of this specification are not limited thereto.

The first bank 127 may be disposed to expose the first electrode E1. The first bank 127 may define an emissive area of a sub-pixel and may be disposed to cover an edge portion (or a peripheral portion) of the first electrode E1.

The first bank 127 may include a black material. For example, the first bank 127 may be formed of a material including a black pigment, or an organic material such as benzocyclobutene resin, polyimide resin, acrylic resin, or a photosensitive polymer, but the embodiments of this specification are not limited thereto. When the first bank 127 is formed of a material including a black pigment or a black dye, the first bank 127 may be a black bank. When the first bank 127 is formed of a material including a black pigment or a black dye, the first bank 127 may block light from the outside or block light reflected from the outside, thereby improving the brightness of the display apparatus. The first bank 127 may serve to absorb light that is reflected again from below the first bank 127 among the light incident from the outside.

The second bank 129 may be disposed on the first bank 127. The second bank 129 may include a transparent material. The second bank 129 may be a transparent bank, but the embodiments of this specification are not limited thereto.

Specifically, the second bank 129 may be disposed on the upper surface or the side surface of the first bank 127. The second bank 129 may also be disposed on at least a portion of the first electrode E1 where the first bank 127 is not disposed. For example, the second bank 129 may be disposed on the side surface or the upper surface of the first electrode E1 located in the concave portion of the third organic insulating layer 125. Accordingly, the second bank 129 may have a higher taper angle compared to the first bank 127. Referring to FIG. 3, the second bank 129 having a high taper angle may have a protruding shape or an angular shape in a plan view.

A spacer 131 may be further disposed on the second bank 129. The spacer 131 may be formed of the same material as the second bank 129, but the embodiments of this specification are not limited thereto. For example, the spacer 131 may be a transparent bank. The spacer 131 may be formed of the same material as the second bank 129 and may be formed simultaneously through a halftone mask, but the embodiments of this specification are not limited thereto.

The first bank 127 and the second bank 129 may include a trench TR. The first bank 127 may form the trench TR by penetrating the second organic insulating layer 123 and the third organic insulating layer 125, and the first bank 127 may fill the trench TR. The second bank 129 may be separated due to the trench TR. The light-emitting layer EL disposed on the second bank 129 may have a reduced thickness in the trench TR region. The light-emitting layer EL with the reduced thickness may have increased resistance, thereby reducing leakage current between adjacent sub-pixels.

The light-emitting layer EL may be disposed on the first electrode E1, the first bank 127, the second bank 129, and the spacer 131. The second electrode E2 may be disposed on the light-emitting layer EL.

The encapsulation layer 400 may be disposed on the second electrode E2. The encapsulation layer 400 may include one or more insulating layers. For example, the encapsulation layer 400 may include a first encapsulation layer 401, a second encapsulation layer 403 located on top of the first encapsulation layer 401, and a third encapsulation layer 405 located on top of the second encapsulation layer 403. The encapsulation layer 400 may include one or more inorganic insulating material layers and one or more organic material layers. For example, the first encapsulation layer 401 and the third encapsulation layer 405 may include inorganic insulating materials, while the second encapsulation layer 403 may include organic materials, but the embodiments of this specification are not limited thereto.

Referring to FIG. 3, the second bank 129 may improve the spreadability of the second encapsulation layer 403 by applying a protruding shape or an angular shape structure. In this specification, applying the protruding shape or angular shape structure to the first bank 127 and the second bank 129 means that the shape formed by the outline of the second bank 129 in a plan view has a protruding shape or an angular shape (or a polygonal shape).

A touch layer 500 may be disposed on the encapsulation layer 400. The touch layer 500 may include a touch buffer layer 501, a first touch conductive layer, a first touch insulating layer 503, a second touch insulating layer 505, and a second touch conductive layer. A third touch insulating layer may be disposed on the second touch conductive layer, but the embodiments of this specification are not limited thereto.

A first touch conductive layer may be disposed on the touch buffer layer 501. The first touch conductive layer may include a bridge electrode 507. The second touch conductive layer, which may include a bridge electrode and a sensor electrode 509 to be described later, may be disposed at a boundary between adjacent sub-pixels. For example, the bridge electrode 507 and the sensor electrode 509 may be disposed in a non-emissive area. The bridge electrode 507 and the sensor electrode 509 may overlap with a black matrix 147, to be described later, and the substrate 101 in a vertical direction. The black matrix 147 may cover the bridge electrode 507 and the sensor electrode 509. As a result, the bridge electrode 507 and the sensor electrode 509 may be prevented from being visible from the outside.

The first touch insulating layer 503 and the second touch insulating layer 505 on the first touch insulating layer 503 may be disposed on the first touch conductive layer. The first touch insulating layer 503 and the second touch insulating layer 505 may prevent or reduce a likelihood of a short circuit between the first touch conductive layer and the second touch conductive layer. The first touch insulating layer 503 may be formed of silicon oxide (SiOₓ), silicon nitride (SiNₓ), or a multilayer thereof, but the embodiments of this specification are not limited thereto. The second touch insulating layer 505 may include an organic insulating material or an inorganic insulating material, but the embodiments of this specification are not limited thereto and may include the same material as the first touch insulating layer 503.

The second touch conductive layer may be disposed on the second touch insulating layer 505. The second touch conductive layer may include a sensor electrode 509.

The sensor electrode 509 may be electrically connected to the bridge electrode 507 through a contact hole formed in the first touch insulating layer 503 and the second touch insulating layer 505.

The sensor electrodes 509 and the bridge electrode 507 may include a metallic material. For example, they may be formed of titanium (Ti), nickel (Ni), aluminum (Al), or an alloy thereof and may be composed of three layers, such as titanium (Ti)/aluminum (Al)/titanium (Ti), but the embodiments of this specification are not limited thereto.

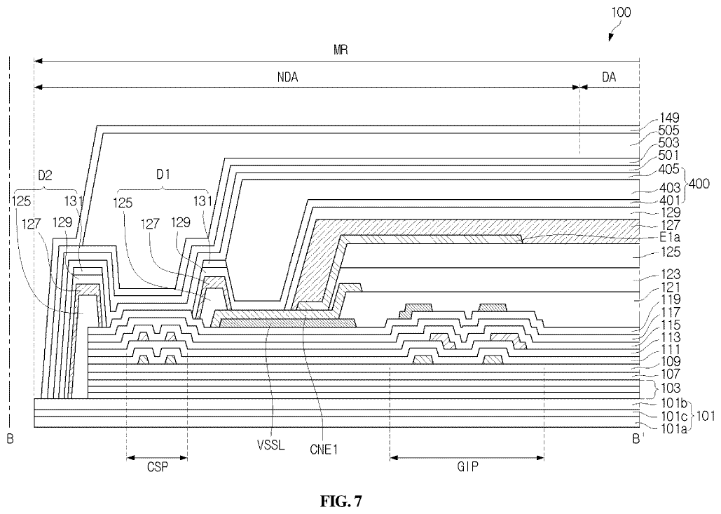

The detailed structure of the touch layer 500 will be described later with reference to FIG. 7.

A cover buffer layer 139 may be disposed on the second touch conductive layer. The cover buffer layer 139 may be formed of an inorganic insulating material, such as silicon nitride SiNₓ or silicon oxide SiOₓ, but the embodiments of this specification are not limited thereto.

A black matrix 147 may be disposed on the cover buffer layer 139. The black matrix 147 may include a black material. For example, the black matrix 147 may include a light-blocking material or a light-absorbing material. For example, the black matrix 147 may be formed of a material including a black pigment or a black dye. The black matrix 147 may cover the bridge electrode 507 and the sensor electrode 509. As a result, the bridge electrode 507 and the sensor electrode 509 may be prevented from being visible from the outside.

A color filter CF may be disposed on the black matrix 147.

The color filter CF may be disposed in each sub-pixel and may block specific colors from the light emitted in the emissive area of each sub-pixel. For example, the color filter disposed in a sub-pixel emitting red light may be configured to block light of colors other than red light. However, the embodiments of this specification are not limited thereto.

The color filter CF may directly contact each of the side surface and the upper surface of the black matrix 147. For example, a plurality of color filters CF may be spaced apart at a boundary between adjacent sub-pixels, but the embodiments of this specification are not limited thereto and may overlap in a vertical direction with respect to the substrate.

A planarization layer 149 may be disposed on the color filter CF. The planarization layer 149 may serve to planarize a step formed by the color filter CF. The planarization layer 149 may include an organic insulating material.

FIG. 5 is an enlarged cross-sectional view of region X in FIG. 4 according to one embodiment. Descriptions that overlap with those previously described with reference to FIG. 4 will be omitted.

Referring to FIG. 5, the third organic insulating layer 125 may have at least one concave portion CON in a sub-pixel area. The third organic insulating layer 125 may surround the concave portion CON and may have a peripheral portion S located around the concave portion CON. The concave portion CON may include a flat portion CONP and an inclined portion CONS surrounding the flat portion CONP.

The flat portion CONP of the concave portion CON may be a portion whose surface is parallel to the surface of the substrate 101, and the inclined portion CONS may be a portion surrounding the flat portion CONP, with the surface of the inclined portion CONS having a predetermined angle relative to the surface of the substrate 101. That is, the surface of the inclined portion CONS may not be parallel to the surface of the substrate 101.

The flat portion CONP of the concave portion may be disposed on the second organic insulating layer 123, and the inclined portion CONS may be formed on the side surface of the third organic insulating layer 125.

The first electrode E1 may be disposed on the peripheral portion S of the third organic insulating layer 125 and on the concave portion CON. In a region overlapping with the concave portion CON, the first electrode E1 may include a first area A1 where the surface of the first electrode E1 is parallel to the surface of the substrate 101, and a second area A2 extending from the first area A1, where the surface of the first electrode E1 has a predetermined angle relative to the surface of the substrate 101. That is, the surface of the second area A2 may not be parallel to the surface of the substrate 101. The first electrode E1 may extend from the second area A2 and include a third area A3 where the surface of the first electrode E1 is parallel to the surface of the substrate 101. The third area A3 may be a region overlapping with the peripheral portion S of the concave portion CON.

The first bank 127 may be disposed on the third organic insulating layer 125 and on a portion of the first electrode E1. The first bank 127 may be disposed to overlap with the peripheral portion S of the concave portion CON provided in the third organic insulating layer 125. The first bank 127 may also be disposed to overlap with the third area A3 of the first electrode E1.

The second bank 129 may be disposed on the first bank 127 and on a portion of the first electrode E1. The second bank 129 may include a first portion P1 and a second portion P2. The first portion P1 and the second portion P2 may be physically connected. The first portion P1 may overlap with the side surface of the first bank 127, the upper surface of the first electrode E1 exposed by the first bank 127, and the first electrode E1 within the concave portion CON. The first portion P1 may contact the side surface of the first bank 127, the upper surface of the first electrode E1 exposed by the first bank 127, and the first electrode E1 within the concave portion CON, respectively. The first portion P1 may not overlap with the upper surface of the first bank 127, but the embodiments of this specification are not limited thereto. The first portion P1 may overlap with or correspond to the concave portion CON.

The second portion P2 may overlap with the upper surface of the first bank 127. The second portion P2 may not overlap with the side surface of the first bank 127, but the embodiments of this specification are not limited thereto. The second portion P2 may correspond to or overlap with the peripheral portion S.

The first bank 127 and the second bank 129 may be disposed to expose a portion of the upper surface of the first electrode E1 in a region overlapping with the concave portion CON. That is, at least one sub-pixel may have a region where the first electrode E1 does not overlap with the first bank 127 and the second bank 129.

The light-emitting layer EL may be disposed on the first electrode E1. The light-emitting layer EL may be formed by a deposition or coating method having directionality. For example, the light-emitting layer EL may be formed by a physical vapor deposition method, such as an evaporation process.

The light-emitting layer EL formed by such a method may have a thickness in a region having a predetermined angle relative to a horizontal plane that is thinner than the thickness in a region parallel to the horizontal plane.

For example, the thickness of the light-emitting layer EL disposed in a region corresponding to the inclined portion CONS of the concave portion CON may be thinner than the thickness of the light-emitting layer EL disposed on the upper surface of the first electrode E1 exposed by the second bank 129. Additionally, the thickness of the light-emitting layer EL disposed in a region corresponding to the inclined portion CONS of the concave portion CON may be thinner than the thickness of the light-emitting layer EL disposed on the peripheral portion S of the concave portion CON.

However, the thickness condition of the light-emitting layer EL in this specification is not limited thereto, and the thickness of the light-emitting layer EL may correspond to the thickness at each position.

The first electrode E1 may include a reflective electrode. The first electrode E1 may be disposed to cover the flat portion CONP and the inclined portion CONS of the concave portion CON of the third organic insulating layer 125.

The second electrode E2 may be formed of a semi-transparent or transparent conductive material. Thus, a portion of the light emitted from the light-emitting layer EL may be reflected by the first electrode E1 in a region corresponding to the inclined portion CONS and extracted to the outside of the panel 100. When a portion of the light emitted from the light-emitting layer EL is reflected by the second area A2 of the first electrode E1 and extracted to the outside, the light may be emitted without being absorbed by the second electrode E2.

At least one sub-pixel may include at least two emissive areas EA1 and EA2. One non-emissive area NEA1 may be disposed between the two emissive areas EA1 and EA2.

Specifically, the first emissive area EA1 may be a region corresponding to a portion of the concave portion CON of the third organic insulating layer 125. The first emissive area EA1 may be a region in the flat portion CONP of the concave portion CON that does not overlap with the first portion P1 of the second bank 129.

In the first emissive area EA1, a portion of the light L1 emitted from the light-emitting layer EL may be emitted through the light-emitting layer EL and the second electrode E2. Additionally, in the first emissive area EA1, a portion of the light L1 emitted from the light-emitting layer EL (hereinafter referred to as the first light in the description below) may reach the first electrode E1, be reflected by the first electrode E1, and then be extracted to the outside of the panel through the light-emitting layer EL and the second electrode E2 in sequence. The first emissive area EA1 may be surrounded by the first non-emissive area NEA1.

The first non-emissive area NEA1 may correspond to a region where the second bank 129 overlaps with the flat portion CONP of the concave portion CON. Specifically, the first non-emissive area NEA1 may correspond to a region where the first portion P1 of the second bank 129 overlaps with the flat portion CONP of the concave portion CON.

The first non-emissive area NEA1 may be a region where a portion of the light L3 emitted from the light-emitting layer EL is directed toward an area corresponding to the first portion P1 of the second bank 129, but the light L3 is not extracted to the outside. In other words, the first non-emissive area NEA1 may be a region where the light emitted from the light-emitting layer EL is emitted in a direction parallel to the flat portion CONP and reaches the first electrode E1, but the light is not reflected to the outside and remains trapped within the sub-pixel.

The second emissive area EA2 may be disposed to surround the first non-emissive area NEA1. The second emissive area EA2 may be a region corresponding to a region where the first electrode E1 overlaps with the inclined portion CONS of the concave portion CON. In another aspect, the second emissive area EA2 may be a region corresponding to the second area A2 of the first electrode E1.

A portion of the light L2 emitted from the light-emitting layer EL (hereinafter referred to as the second light) may be directed toward a region corresponding to the second area A2 of the first electrode E1.

Specifically, the second light L2 passes through the first portion P1 of the second bank 129 and reaches a region corresponding to a portion of the second area A2 of the first electrode E1. The second light L2 that reaches the first electrode E1 is reflected by the first electrode E1 and extracted to the outside through the first portion P1 of the second bank 129, the light-emitting layer EL, and the second electrode E2 in sequence. As the second light L2 is extracted in this manner, the second emissive area EA2 is formed.

The color coordinates of the first emissive area EA1 and the second emissive area EA2 may correspond to each other. For example, the color of the light emitted by the first emissive area EA1 and the second emissive area EA2 may be the same. However, the emission luminance of the first emissive area EA1 and the second emissive area EA2 may differ, but this specification is not limited thereto.

The first non-emissive area NEA1, disposed between the first emissive area EA1 and the second emissive area EA2, may be a region where visible light from the first emissive area EA1 and visible light from the second emissive area EA2 are mixed, but this specification is not limited thereto.

The second non-emissive area NEA2 may be disposed to surround the second emissive area EA2. The second non-emissive area NEA2 may correspond to a region where the second portion P2 of the second bank 129 is disposed.

FIG. 6 is a cross-sectional view of the touch layer 500 according to FIG. 4 according to one embodiment. Descriptions that overlap with those previously described with reference to FIG. 4 will be omitted.

Referring to FIG. 6, the second touch conductive layer may be disposed on the second touch insulating layer 505. The second touch conductive layer may include a first sensor electrode 509a and a second sensor electrode 509b. The sensor electrode 509 may include the first sensor electrode 509a extending in a first direction DR1 as shown in FIG. 1, and the second sensor electrode 509b extending in a second direction DR2 as shown in FIG. 1, the second direction DR2 being perpendicular to the first direction DR1.

The bridge electrode 507 may be electrically connected to the first sensor electrode 509a through a contact hole formed in the first touch insulating layer 503 and the second touch insulating layer 505. For example, the first sensor electrode 509a and the bridge electrode 507 may extend in the first direction DR1 (FIG. 1).

FIG. 7 is a cross-sectional view taken along line B-B′ of FIG. 1 according to one embodiment.

Referring to FIG. 7, at least one panel inorganic layer 103, 107, 109, 111, 113, 115, 117, 119 may not extend to the end of the substrate 101. That is, at least one panel inorganic layer 103, 107, 109, 111, 113, 115, 117, 119 may expose the end of the substrate 101, but the embodiments of this specification are not limited thereto.

In an embodiment, the display panel 100 may further include a crack detection pattern CSP, a low-potential voltage line VSSL, and a gate driving unit GIP. As described in FIG. 1, the low-potential voltage line VSSL may be located between the crack detection pattern CSP and the display area DA, and the gate driving unit GIP may be located between the low-potential voltage line VSSL and the display area DA.

For example, the gate driver GIP may be composed of a conductive layer located in the same layer as the first gate electrode 207 (FIG. 4), a conductive layer located in the same layer as the second light-shielding layer 114 (FIG. 4), or a conductive layer located in the same layer as the first source electrode 201 (FIG. 7), but the embodiments of this specification are not limited thereto.

For example, the crack detection pattern CSP may be disposed between the first dam D1 and the second dam D2. The crack detection pattern CSP may be composed of a conductive layer located in the same layer as the first gate electrode 207 as shown in FIG. 4, or a conductive layer located in the same layer as the second light-shielding layer 114 as shown in FIG. 4, but the embodiments of this specification are not limited thereto. For example, the crack detection pattern CSP may include a conductive layer positioned in the same layer as the first source electrode 201, but the embodiments of this specification are not limited thereto.

The low-potential voltage line VSSL may be arranged between the crack detection pattern CSP and the gate driving unit GIP. The low-potential voltage line VSSL may be composed of a conductive layer positioned in the same layer as the first source electrode 201, but the embodiments of this specification are not limited thereto.

The first organic insulating layer 121 may cover the gate driver GIP, partially cover one end of the low-potential voltage line VSSL, and expose another portion of the low-potential voltage line VSSL. In this specification, one end refers to the area located in the direction towards the display area DA from a non-display area NDA, and the other end refers to the area located in the direction towards the non-display area NDA from a display area DA.

The organic insulating layer 121 may have the first connection electrode CNE1 arranged in the same layer as the connection electrode 122. The organic insulating electrode CNE1 may be directly connected to the area of the low-potential voltage line VSSL exposed by the first protective layer 121. The first connection electrode CNE1 may cover the other end of the low-potential voltage line VSSL, but the embodiments of this specification are not limited thereto.

The second organic insulating layer 123 may be disposed on the first connection electrode CNE1. The second organic insulating layer 123 may directly contact and cover one end of the first connection electrode CNE1 and may expose another portion of the first connection electrode CNE1.

The third organic insulating layer 125 may be disposed on the second organic insulating layer 123.

The third organic insulating layer 125 may constitute the first layer of the first dam D1 and the first layer of the second dam D2. The second dam D2 may overlap with, for example, the low-potential voltage line VSSL and cover the other end of the low-potential voltage line VSSL. The second dam D2 may directly contact the first connection electrode CNE and cover the other end of the first connection electrode CNE1. The third organic insulating layer 125, constituting the first layer of the first dam D1, may directly contact the exposed side surface of at least one of panel inorganic layer 103, 107, 109, 111, 113, 115, and 117, and 119, and may directly contact the upper surface of the substrate 101, but the embodiments of this specification are not limited thereto. The third organic insulating layer 125 may overlap with the gate driver GIP. Although the dam is illustrated as consisting of two parts in this specification, the dam may be composed of three or more parts, or even just one part.

A low-potential connection electrode Ela, located in the same layer as the first electrode E1 as shown in FIG. 4, may be disposed on the first connection electrode CNE1 and the third organic insulating layer 125, which are exposed by the third organic insulating layer 125. The low-potential connection electrode E1a may be electrically connected to the first connection electrode CNE1 exposed by the third organic insulating layer 125. The low-potential connection electrode E1a may be electrically connected to the second electrode E2 as shown in FIG. 4.

The first bank 127 and the second bank 129 may be disposed on the low-potential connection electrode E1a and the third organic insulating layer 125. The first bank 127 and the second bank 129 may overlap with the gate driver GIP, overlap with the low-potential connection electrode Ela, and cover the other end of the low-potential connection electrode Ela. The first bank 127 and the second bank 129 may completely cover the low-potential connection electrode Ela, but the embodiments of this specification are not limited thereto. The first bank 127 and the second bank 129 may expose the central portion and the other end of the first connection electrode CNE1, but the embodiments of this specification are not limited thereto. The first bank 127 may constitute the second layer of the first dam D1 and the second layer of the second dam D2. In each dam D1 and D2, the first bank 127 may overlap with the third organic insulating layer 125 constituting the first layer and may completely cover the third organic insulating layer 125, but the embodiments of this specification are not limited thereto. In the second dam D2, the first bank 127 may contact the side surface of the third organic insulating layer 125 and contact the upper surface of the substrate 101, but the embodiments of this specification are not limited thereto. The second bank 129 may constitute the third layer of the dams D1 and D2. The second bank 129, constituting the third layer of each dam D1 and D2, may overlap with the first bank 127 constituting the second layer and may completely cover the first bank 127, but the embodiments of this specification are not limited thereto. In the second dam D2, the second bank 129 may contact the side surface of the first bank 127 and contact the upper surface of the substrate 101, but the embodiments of this specification are not limited thereto.

The spacer 131 may constitute the fourth layer of the first dam D1 and the fourth layer of the second dam D2. In each dam D1 and D2, the spacer 131 may overlap with the second bank 129 constituting the third layer. In the second dam D2, the spacer 131 may overlap with the second bank 129 constituting the third layer.

An encapsulation layer 400 may be disposed on the spacer 131. The first encapsulation layer 401 extends to the gate driving unit GIP, the low-potential voltage line VSSL, the first dam D1, and the second dam D2, and may cover the outer surface of the second dam D2. The second encapsulation layer 403 may terminate at the first dam D1. The second encapsulation layer 403 may overlap with the gate driving unit GIP and the low-potential voltage line VSSL. The third encapsulation layer 405 extends to the gate driving unit GIP, the low-potential voltage line VSSL, the first dam D1, and the second dam D2, and may directly contact the first encapsulation layer 401 on the first dam D1, the crack detection pattern CSP, and the second dam D2.

The touch buffer layer 501 and the first touch insulating layer 503 extend to the gate driving unit GIP, the low-potential voltage line VSSL, the first dam D1, and the second dam D2, and may cover the outer surface of the second dam D2. The second touch insulating layer 505 may extend to the gate driver GIP, the low-potential voltage line VSSL, the first dam D1, and the crack detection pattern CSP, and may stop on the second dam D2, but the embodiments of this specification are not limited thereto.

The cover buffer layer 139 may extend to the gate driver GIP, the low-potential voltage line VSSL, the first dam D1, and the second dam D2, and may directly contact the outer side surface of the second touch insulating layer 505, but the embodiments of this specification are not limited thereto.

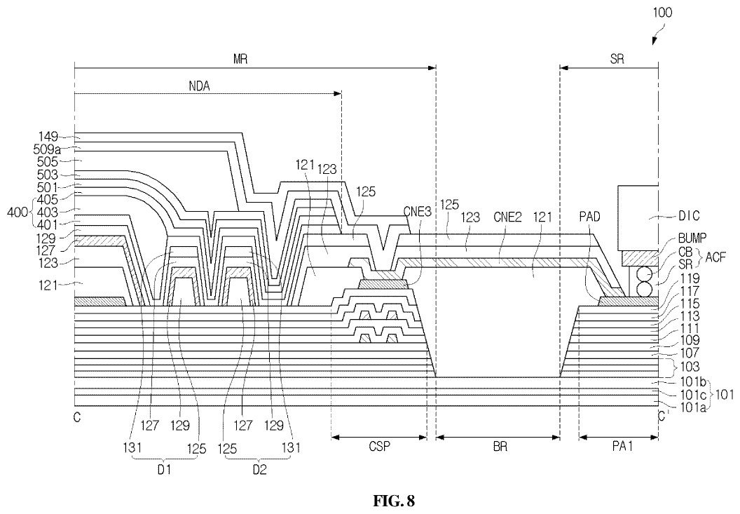

FIG. 8 is a cross-sectional view taken along line C-C′ of FIG. 1 according to one embodiment.

Referring to FIGS. 4, 7, and 8, a bending region BR may be disposed between the sub-region SR and the crack detection pattern CSP. In the bending region BR, the panel inorganic layers 103, 107, 109, 111, 113, 115, 117, and 119 may be removed to expose the upper surface of the substrate 101.

In the first pad area PA1, a pad electrode PAD disposed in the same layer as the first source electrode 201 (see FIG. 4) is arranged, and a third connection electrode CNE3 disposed in the same layer as the first source electrode 201 (see FIG. 4) may be arranged on the crack detection pattern CSP.

The first organic insulating layer 121 may be disposed on the pad electrode PAD and the third connection electrode CNE3. In the bending region BR, the first organic insulating layer 121 may be disposed, and the first organic insulating layer 121 may directly contact the upper surface of the substrate 101 and, in the bending region BR, may directly contact the side surface of the panel inorganic layers 103, 107, 109, 111, 113, 115, 117, and 119.

The second connection electrode CNE2 may be disposed on the first organic insulating layer 121, and the second connection electrode CNE2 may be disposed in the same layer as the connection electrode 122 as shown in FIG. 4. The second connection electrode CNE2 may electrically connect the pad electrode PAD and the third connection electrode CNE3. The second connection electrode CNE2 may be arranged across the bending region BR and the first pad area PA1 and above the crack detection pattern CSP.

The data driver DIC may be arranged on the pad electrode PAD. The data driver DIC includes bumps BUMP, and an anisotropic conductive film ACF is disposed between the pad electrode PAD and the bumps BUMP, electrically connecting the pad electrode PAD and the bumps BUMP. The anisotropic conductive film ACF may contain a plurality of conductive balls CB dispersed in a resin RS. Through the conductive balls CB, the pad electrode PAD, and the bumps BUMP may be electrically connected.

The second organic insulating layer 123 may be disposed on the second connection electrode CNE2. The second organic insulating layer 123 may expose the pad electrode PAD.

The third organic insulating layer 125 may be disposed on the second organic insulating layer 123. The third organic insulating layer 125 may expose the pad electrode PAD.

The first encapsulation layer 401 and the third encapsulation layer 405 of the encapsulation layer 400 may extend up to a point before the bending region BR. For example, the first encapsulation layer 401 and the third encapsulation layer 405 may extend up to a point before the crack detection pattern CSP, but the embodiments of this specification are not limited thereto and may also overlap with the crack detection pattern CSP. The first encapsulation layer 401 and the third encapsulation layer 405 may not be disposed in the bending region BR.

The touch buffer layer 501 and the first touch insulating layer 503 may extend up to the bending region BR. For example, the touch buffer layer 501 and the first touch insulating layer 503 may extend up to the crack detection pattern CSP and may also overlap with the crack detection pattern CSP, but the embodiments of this specification are not limited thereto. The touch buffer layer 501 and the first touch insulating layer 503 may not be disposed in the bending region BR.

The second touch insulating layer 505 may overlap with the first dam D1 and the second dam D2. The second touch insulating layer 505 may not be disposed on the outer side of the second dam D2, but the embodiments of this specification are not limited thereto.

The touch connection line may be electrically connected to the second connection electrode CNE2. The touch connection line may serve to provide a signal applied from the pad electrode PAD and the second connection electrode CNE2 to the first sensor electrode 509a or the second sensor electrode 509b as shown in FIG. 6. The touch connection line may be located in the same layer as the second touch conductive layer including the first sensor electrode 509a as shown in FIG. 4, but the embodiments of this specification are not limited thereto and may be located in the same layer as the first touch conductive layer including the bridge electrode 507 as shown in FIG. 4, or may be composed of both the first and second touch conductive layers, but the embodiments of this specification are not limited thereto.

The planarization layer 149 may be disposed on the touch connection line, and the planarization layer 149 may not be disposed in the bending region BR.

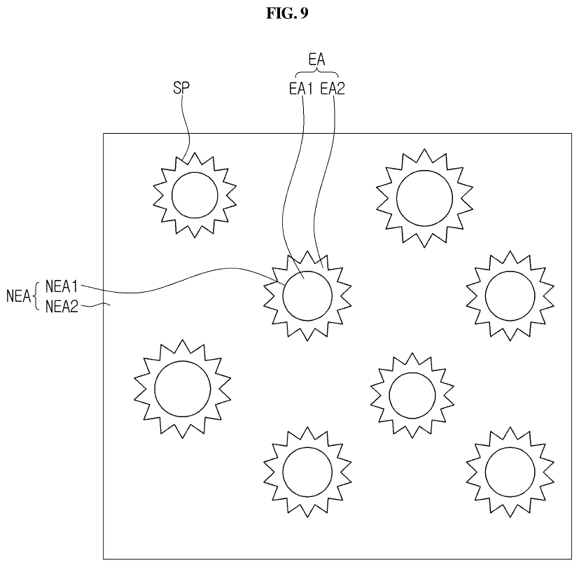

FIG. 9 is a plan view illustrating the arrangement of sub-pixels in the display area of FIG. 1 according to an alternative embodiment.

Referring to FIG. 9, the first emissive area EA1 and the second emissive area EA2 may have different shapes in a plan view. For example, the first emissive area EA1 may have a circular shape in a plan view. The second emissive area EA2 may have a protruding shape with a plurality of protrusions in a plan view. The embodiments of this specification are not limited thereto. Referring to FIG. 4, the first bank 127 and the second bank 129 may improve the spreadability of the second encapsulation layer 403 by applying a protruding shape or an angular shape structure.

The display apparatus according to various embodiments of this specification may be described as follows.

A display apparatus according to various embodiments of this specification may include a substrate including a display area having a plurality of sub-pixels and a non-display area surrounding the display area, a first thin-film transistor and a second thin-film transistor disposed on the substrate and spaced apart from each other, a plurality of organic insulating layers disposed on the first thin-film transistor and the second thin-film transistor, the plurality of organic insulating layers having at least one concave portion, a first electrode disposed on a peripheral portion located around the concave portion and on the concave portion, a first bank and a second bank, including a first portion disposed on the first electrode in the corresponding area of the concave portion and a second portion disposed on the first electrode and the organic insulating layer in the corresponding area of the periphery, an organic layer overlapping with the concave portion and disposed on the first electrode, a second electrode disposed on the organic layer and the second bank, a plurality of encapsulation layers disposed on the second electrode, a touch layer disposed on the plurality of encapsulation layers, and a color filter layer disposed on the touch layer.

In the display apparatus according to various embodiments of this specification, the first bank may include a black material, and the second bank may include a transparent material.

In the display apparatus according to various embodiments of this specification, the plurality of organic insulating layers may include at least a first organic insulating layer, a second organic insulating layer, and a third organic insulating layer stacked sequentially.

In the display apparatus according to various embodiments of this specification, the first bank may further comprise a trench penetrating the second organic insulating layer and the third organic insulating layer.

In the display apparatus according to various embodiments of this specification, the concave portion may be formed in the third organic insulating layer, and the concave portion may include a flat portion and an inclined portion surrounding the flat portion.

In the display apparatus according to various embodiments of this specification, the first electrode may include a reflective electrode.

In the display apparatus according to various embodiments of this specification, the flat portion of the concave portion may include a region where the first portion of second the bank and the first electrode do not overlap and corresponds to a first emissive area of each of the plurality of sub-pixels.

The display apparatus according to various embodiments of this specification may further include a second emissive area surrounding the first emissive area, wherein the second emissive area may correspond to a region where the first electrode overlaps with the inclined portion of the concave portion.

In the display apparatus according to various embodiments of this specification, color coordinates of the first emissive area may correspond to color coordinates of the second emissive area.

The display apparatus according to various embodiments of this specification may further include a first non-emissive area disposed between the first emissive area and the second emissive area.

In the display apparatus according to various embodiments of this specification, the first non-emissive area may correspond to a region where the first portion of the second bank overlaps with the flat portion of the concave portion.

The display apparatus according to various embodiments of this specification may further include a second non-emissive area surrounding the second emissive area.

In the display apparatus according to various embodiments of this specification, the second non-emissive area may correspond to a region where the second portion of the second bank is disposed.

In the display apparatus according to various embodiments of this specification, the display apparatus further comprise a black matrix disposed on the touch layer, the touch layer comprises a bridge electrode and a sensor electrode disposed on the bridge electrode, and the black matrix overlaps with the bridge electrode and the sensor electrode.

The display apparatus according to various embodiments of this specification may further include a connection electrode disposed on the first organic insulating layer, and the first electrode is connected with the second thin-film transistor by a contact hole penetrating the second organic insulating layer and the third organic insulating layer.

In the display apparatus according to various embodiments of this specification, the connection electrode is disposed in a bending region.

In the display apparatus according to various embodiments of this specification, the first thin-film transistor may include a polycrystalline semiconductor layer, a first gate electrode, a first source electrode, and a first drain electrode, the second thin-film transistor may include an oxide semiconductor layer, a second gate electrode, a second source electrode, and a second drain electrode.

In the display apparatus according to various embodiments of this specification, each of the first emissive area, and the second emissive area and the first non-emissive area may have a protruding shape with a plurality of protrusions in a plan view.

In the display apparatus according to various embodiments of this specification, the second bank may have a protruding shape or an angular shape in a plan view.

The embodiments of this specification are advantageous for providing a display apparatus with improved light extraction efficiency.

The embodiments of this specification are advantageous for providing a display apparatus capable of improving the spreadability of a third encapsulation layer (or organic encapsulation layer) by applying a protruding structure or an angular structure to a second bank.

The embodiments of this specification are advantageous for providing a display apparatus having a structure capable of preventing color mixing between adjacent sub-pixels.

The embodiments of this specification are advantageous for providing a display apparatus capable of reducing leakage current between adjacent sub-pixels by forming trenches in an organic insulating layer and a second bank, increasing the resistance of a thinned light-emitting layer.

The effects of this specification are not limited to the aforesaid, and other effects not described herein with be clearly understood by those skilled in the art from the descriptions of the claims.

### DESCRIPTION OF REFERENCE NUMERALS

1: display apparatus
100: display panel
DA: display area
NDA: non-display area
PX: pixel

What is claimed is:

1. A display apparatus comprising:
a substrate including a display area having a plurality of sub-pixels and a non-display area surrounding the display area;
a first thin-film transistor and a second thin-film transistor on the substrate, the first thin-film transistor and the second thin-film transistor spaced apart from each other;
a plurality of organic insulating layers on the first thin-film transistor and the second thin-film transistor, the plurality of organic insulating layers having at least one concave portion;
a first electrode on a peripheral portion located around the at least one concave portion and on the at least one concave portion;
a first bank on the first electrode;
a second bank on the first bank, the second bank including a first portion on the first electrode in a region corresponding to the at least one concave portion and a second portion on the first electrode and an organic insulating layer from the plurality of organic insulating layers that is in a region corresponding to the peripheral portion;
an organic layer overlapping with the at least one concave portion, the organic layer on the first electrode;
a second electrode on the organic layer and the second bank;
a plurality of encapsulation layers on the second electrode;
a touch layer on the plurality of encapsulation layers; and
a color filter layer on the touch layer.

2. The display apparatus of claim 1, wherein the first bank comprises a black material and the second bank comprises a transparent material.

3. The display apparatus of claim 1, wherein the plurality of organic insulating layers comprises at least a first organic insulating layer, a second organic insulating layer, and a third organic insulating layer that are stacked sequentially.

4. The display apparatus of claim 3, wherein the first bank further comprises a trench penetrating the second organic insulating layer and the third organic insulating layer.

5. The display apparatus of claim 3, wherein the at least one concave portion is in the third organic insulating layer, and the at least one concave portion comprises a flat portion and an inclined portion surrounding the flat portion.

6. The display apparatus of claim 1, wherein the first electrode comprises a reflective electrode.

7. The display apparatus of claim 5, wherein the flat portion of the at least one concave portion comprises a region where the first portion of the second bank and the first electrode are non-overlapping and corresponds to a first emissive area of each of the plurality of sub-pixels.

8. The display apparatus of claim 7, further comprising:
a second emissive area surrounding the first emissive area,
wherein the second emissive area corresponds to a region where the first electrode overlaps with the inclined portion of the at least one concave portion.

9. The display apparatus of claim 8, wherein color coordinates of the first emissive area correspond to color coordinates of the second emissive area.

10. The display apparatus of claim 8, further comprising:
a first non-emissive area between the first emissive area and the second emissive area.

11. The display apparatus of claim 10, wherein the first non-emissive area corresponds to a region where the first portion of the second bank overlaps with the flat portion of the at least one concave portion.

12. The display apparatus of claim 8, further comprising:
a second non-emissive area surrounding the second emissive area.

13. The display apparatus of claim 12, wherein the second non-emissive area corresponds to a region where the second portion of the second bank is disposed.

14. The display apparatus of claim 1, further comprising:
a black matrix on the touch layer, the touch layer comprising a bridge electrode and a sensor electrode on the bridge electrode,
wherein the black matrix overlaps with the bridge electrode and the sensor electrode.

15. The display apparatus of claim 3, further comprising:
a connection electrode on the first organic insulating layer,
wherein the first electrode is connected with the second thin-film transistor by a contact hole penetrating the second organic insulating layer and the third organic insulating layer.

16. The display apparatus of claim 15, wherein the connection electrode is in a bending region.

17. The display apparatus of claim 1, wherein the first thin-film transistor includes a polycrystalline semiconductor layer, a first gate electrode, a first source electrode, and a first drain electrode, and the second thin-film transistor includes an oxide semiconductor layer, a second gate electrode, a second source electrode, and a second drain electrode.

18. The display apparatus of claim 10, wherein each of the first emissive area, and the second emissive area and the first non-emissive area has a protruding shape with a plurality of protrusions in a plan view.

19. The display apparatus of claim 1, wherein the second bank has a protruding shape or an angular shape in a plan view.
